(19) United States
(12) Patent Application Publication
(10) Pub. No.: US 2026/0082607 A1
(43) Pub. Date: Mar. 19, 2026

(54) NANOSTRUCTURE PATTERNING FOR MULTI-GATE TRANSISTORS

(71) Applicant: Taiwan Semiconductor Manufacturing Company, Ltd., Hsinchu (TW)

(72) Inventors: Hung-Yao Chen, Hsinchu (TW); Shun-Siang Jhan, Kaohsiung City (TW); Ta-Chun Ma, New Taipei City (TW); Hsueh-Chang Sung, Hsinchu County (TW); Ming-Hua Yu, Hsinchu (TW); Chii-Horng Li, Hsinchu County (TW)

(21) Appl. No.: 18/889,706

(22) Filed: Sep. 19, 2024

(51) Int. Cl. H01L 29/66; H01L 21/02; H01L 21/3065; H01L 29/06; H01L 29/423; H01L 29/775; H01L 29/786

(52) U.S. Cl. CPC H10D 30/014; H10D 30/43; H10D 30/6735; H10D 30/6757; H10D 62/121; H10D 64/017; H10D 64/018; H10P 50/242; H10P 70/20

(57) ABSTRACT

Semiconductor devices and methods of forming the same are provided. A method according to the present disclosure includes a substrate and a fin-shaped that include sacrificial layers interleaved by channel layers, forming a dummy gate stack over the fin-shaped structure, forming a gate spacer layer along sidewalls of the dummy gate stack, forming source/drain trenches in the fin-shaped structure, partially etching the sacrificial layers to form inner spacer recesses, forming inner spacer features in the inner spacer recesses, forming source/drain features in the source/drain trenches, removing the dummy gate stack, selectively etching the sacrificial layers to release the channel layers channel members, cleaning the plurality of channel members, epitaxially depositing a semiconductor layer over the channel members, annealing the semiconductor layer, and forming a gate structure to wrap around each of the channel members.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

For example, as integrated circuit (IC) technologies progress towards smaller technology nodes, multi-gate devices have been introduced to improve gate control by increasing gate-channel coupling, reducing off-state current, and reducing short-channel effects (SCEs). A multi-gate device generally refers to a device having a gate structure, or portion thereof, disposed over more than one side of a channel region. Fin-like field effect transistors (FinFETs) and gate-all-around (GAA) transistors are examples of multi-gate devices that have become popular and promising candidates for high performance and low leakage applications. A FinFET has an elevated channel wrapped by a gate on more than one side (for example, the gate wraps a top and sidewalls of a “fin” of semiconductor material extending from a substrate). A GAA transistor has a gate structure that can extend, partially or fully, around a channel region to provide access to the channel region on two or more sides. Because its gate structure surrounds the channel regions, a GAA transistor may also be referred to as a surrounding gate transistor (SGT) or a multi-bridge-channel (MBC) transistor. The channel region of a GAA transistor may include nanowires, nanosheets, or other nanostructures and for that reason, a GAA transistor may also be referred to as a nanowire transistor or a nanosheet transistor. Fabricating GAA transistors is not without its challenges.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flowchart of a method for forming a semiconductor device, according to one or more aspects of the present disclosure.

FIGS. 2-18 illustrate fragmentary cross-sectional views of a work-in-progress (WIP) structure during a fabrication process according to the method of FIG. 1, according to one or more aspects of the present disclosure.

FIGS. 19, 20 and 21 illustrate enlarged cross-sectional view of a channel region of a semiconductor device along a gate width direction according to one or more aspects of the present disclosure.

FIGS. 22 and 23 illustrate enlarged cross-sectional views of a channel region of a semiconductor device along a gate length direction according to one or more aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Still further, when a number or a range of numbers is described with “about,” “approximate,” and the like, the term is intended to encompass numbers that are within +/−10% of the number described, unless otherwise specified. For example, the term “about 5 nm” encompasses the dimension range from 4.5 nm to 5.5 nm.

The present disclosure is generally related to multi-gate transistors and fabrication methods, and more particularly to patterning of the channel members of multi-gate transistors.

As described above, a GAA transistor has a gate structure that can extend, partially or fully, around a channel region to provide access to the channel region on two or more sides. A GAA transistor may include more than one nano-sized channel members stacked one over another. In some technologies, the channel members are released after sacrificial layers of a different semiconductor composition. In these technologies, the sacrificial layers and the semiconductor layers that are released as channel members may undergo certain thermal cycles, such as at least one anneal process to form source/drain features. These thermal cycles may cause inter-diffusion or intermixing at interfaces of the channel layers and the sacrificial layers. The intermixed layer has a composition different from that of the channel layers or that of the sacrificial layers.

The present disclosure provides embodiments of a semiconductor device. The semiconductor device includes a plurality of channel members extending between two source/drain features. Each of the channel members is divided into a channel portion wrapped around by a gate structure and a connection portion sandwiched either between a gate spacer layer and an inner spacer feature or between two inner spacer features. An inner spacer feature according to the present disclosure includes an inner layer and an outer layer. A dielectric constant of the outer layer is greater than a dielectric constant of the inner layer. The outer layer and the inner layer may include silicon, carbon, oxygen, and nitrogen. An oxygen content of the outer layer is smaller than an oxygen content of the inner layer and a nitrogen content of the outer layer is greater than a nitrogen content of the inner layer. A portion of the outer layer facing the gate structure may be etched away along with the sacrificial layers such that the gate structure is in contact with the inner layer. The channel members of the present disclosure may not be straight. In some implementations, a channel member may include a first ridge and an opposing second ridge at the interface between an inner spacer feature and the gate structure. In some instances, the first and second ridge may partially extend between the inner spacer feature and the gate structure. With the outer layer, the inner spacer features of the present disclosure may have sufficient etch resistance to prevent damages to the source/drain features. The portion of the outer layer between the source/drain feature and the gate structure may be removed. Because the dielectric constant of the inner layer is smaller than that of the outer layer, the removal of the portion of the outer layer may reduce parasitic capacitance and improve device performance.

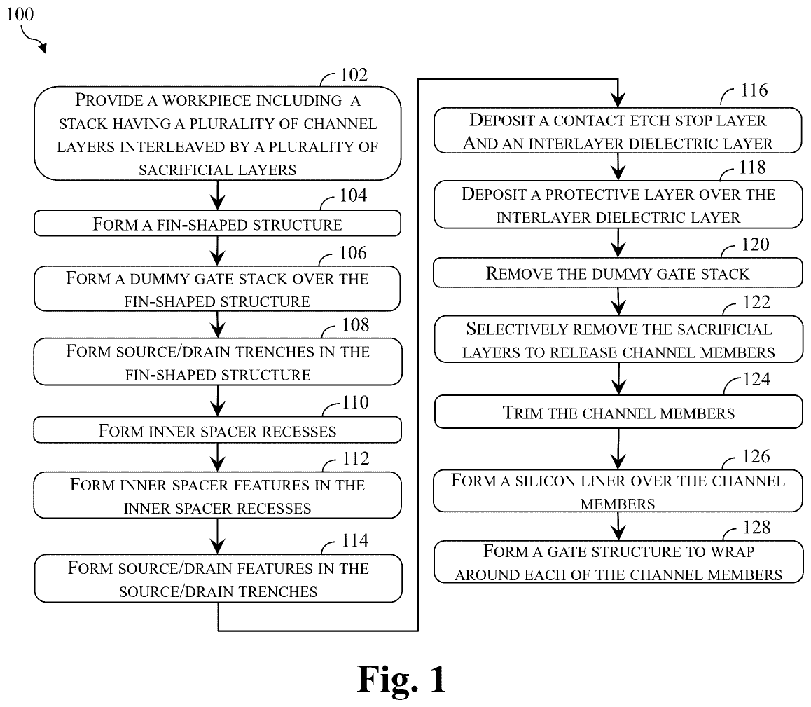

The various aspects of the present disclosure will now be described in more detail with reference to the figures. FIG. 1 illustrates a flowchart of a method 100 of forming a semiconductor device from a WIP structure according to one or more aspects of the present disclosure. Method 100 is merely an example and is not intended to limit the present disclosure to what is explicitly illustrated in method 100. Additional steps may be provided before, during and after method 100, and some steps described can be replaced, eliminated, or moved around for additional embodiments of the methods. Not all steps are described herein in detail for reasons of simplicity. Method 100 is described below in conjunction with fragmentary cross-sectional views of the WIP structure at different stages of fabrication according to embodiments of method 100.

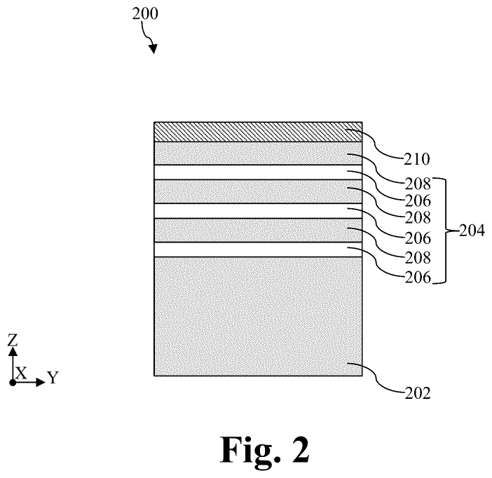

Referring to FIGS. 1 and 2, method 100 includes a block 102 where a WIP structure 200 is provided. It is noted that because the WIP structure 200 will be fabricated into a semiconductor device, the WIP structure 200 may also be referred to as the semiconductor device 200 as the context requires. The WIP structure 200 may include a substrate 202. Although not explicitly shown in the figures, the substrate 202 may include an n-type well region and a p-type well region for fabrication of transistors of different conductivity types. In one embodiment, the substrate 202 may be a silicon (Si) substrate. In some other embodiments, the substrate 202 may include other semiconductors such as germanium (Ge), silicon germanium (SiGe), or a III-V semiconductor material. Example III-V semiconductor materials may include gallium arsenide (GaAs), indium phosphide (InP), gallium phosphide (GaP), gallium nitride (GaN), gallium arsenide phosphide (GaAsP), aluminum indium arsenide (AlInAs), aluminum gallium arsenide (AlGaAs), gallium indium phosphide (GaInP), and indium gallium arsenide (InGaAs). The substrate 202 may also include an insulating layer, such as a silicon oxide layer, to have a silicon-on-insulator (SOI) structure. When present, each of the n-type well and the p-type well is formed in the substrate 202 and includes a doping profile. An n-type well may include a doping profile of an n-type dopant, such as phosphorus (P) or arsenic (As). A p-type well may include a doping profile of a p-type dopant, such as boron (B). The doping in the n-type well and the p-type well may be formed using ion implantation or thermal diffusion and may be considered portions of the substrate 202. For avoidance of doubts, the X direction, the Y direction and the Z direction are perpendicular to one another.

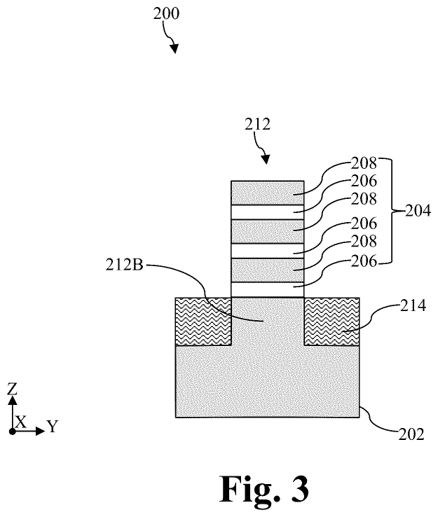

As shown in FIG. 2, the WIP structure 200 also includes a stack 204 disposed over the substrate 202. The stack 204 includes a plurality of channel layers 208 interleaved by a plurality of sacrificial layers 206. The channel layers 208 and the sacrificial layers 206 may have different semiconductor compositions. In some implementations, the channel layers 208 are formed of silicon (Si) and sacrificial layers 206 are formed of silicon germanium (SiGe). In these implementations, the additional germanium content in the sacrificial layers 206 allow selective removal or recess of the sacrificial layers 206 without substantial damages to the channel layers 208. In some embodiments, the sacrificial layers 206 and channel layers 208 may be deposited using an epitaxial process. Suitable epitaxial processes include vapor-phase epitaxy (VPE), ultra-high vacuum chemical vapor deposition (UHV-CVD), molecular beam epitaxy (MBE), and/or other suitable processes. As shown in FIG. 2, the sacrificial layers 206 and the channel layers 208 are deposited alternatingly, one-after-another, to form the stack 204. It is noted that three (3) layers of the sacrificial layers 206 and three (3) layers of the channel layers 208 are alternately and vertically arranged as illustrated in FIG. 3, which are for illustrative purposes only and not intended to be limiting beyond what is specifically recited in the claims. It can be appreciated that any number of sacrificial layers and channel layers can be formed in the stack 204. The number of layers depends on the desired number of channels members for the device 200. In some embodiments, the number of the channel layers 208 is between 2 and 10. For patterning purposes, a hard mask layer 210 may be deposited over the stack 204. The hard mask layer 210 may be a single layer or a multilayer. In one example, the hard mask layer 210 includes a silicon oxide layer and a silicon nitride layer.

Referring to FIGS. 1 and 3, method 100 includes a block 104 where a fin-shaped structure 212 is formed from the stack 204. In some embodiments, the stack 204 and a portion of the substrate 202 are patterned to form the fin-shaped structure 212. As shown in FIG. 3, the fin-shaped structure 212 extends vertically along the Z direction from the substrate 202. The fin-shaped structure 212 includes a base portion 212B (or base fin 212B) formed from the substrate 202 and a stack portion formed from the stack 204. The fin-shaped structure 212 may be patterned using suitable processes including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a material layer is formed over a substrate and patterned using a photolithography process. Spacers are formed alongside the patterned material layer using a self-aligned process. The material layer is then removed, and the remaining spacers, or mandrels, may then be used to pattern the fin-shaped structure 212 by etching the stack 204 and the substrate 202. The etching process can include dry etching, wet etching, reactive ion etching (RIE), and/or other suitable processes.

As shown in FIG. 3, operations at block 104 also include formation of an isolation feature 214 adjacent and around the base portion of the fin-shaped structure 212. The isolation feature 214 is disposed between the fin-shaped structure 212 and another fin-shaped structure 212. The isolation feature 214 may also be referred to as a shallow trench isolation (STI) feature 214. In an example process, a dielectric layer is first deposited over the WIP structure 200, filling the trenches between the fin-shaped structure 212 and a neighboring fin-shaped structure with the dielectric material. In some embodiments, the dielectric layer may include silicon oxide, silicon nitride, silicon oxynitride, fluorine-doped silicate glass (FSG), a low-k dielectric, combinations thereof, and/or other suitable materials. In various examples, the dielectric layer may be deposited by a CVD process, a subatmospheric CVD (SACVD) process, a flowable CVD process, an atomic layer deposition (ALD) process, a physical vapor deposition (PVD) process, spin-on coating, and/or other suitable process. The deposited dielectric material is then thinned and planarized, for example by a chemical mechanical polishing (CMP) process. The planarized dielectric layer is further recessed by a dry etching process, a wet etching process, and/or a combination thereof to form the isolation feature 214. As shown in FIG. 3, the stack portion of the fin-shaped structure 212 rises above the isolation feature 214. Although not explicitly shown in FIG. 3, the hard mask layer 210 may also be removed during the formation of the isolation feature 214.

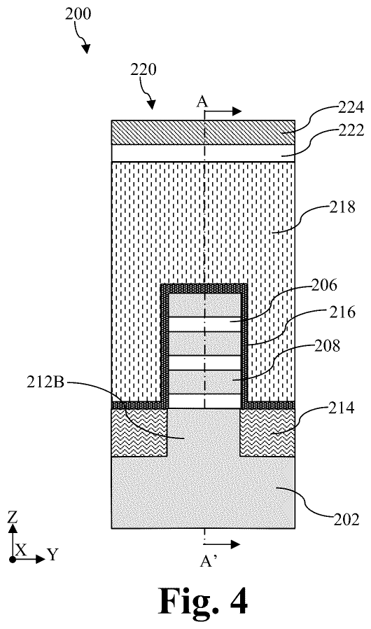

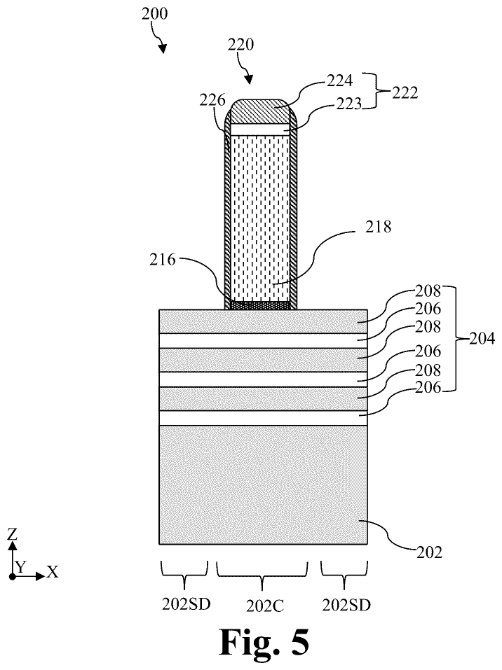

Referring to FIGS. 1, 4 and 5, method 100 includes a block 106 where a dummy gate stack 220 is formed over the fin-shaped structure 212. In some embodiments, a gate replacement process (or gate-last process) is adopted where the dummy gate stack 220 serves as placeholders for a functional gate structure. Other processes and configuration are possible. In some embodiments, the dummy gate stack 220 is formed over the isolation feature 214 and is at least partially disposed over the fin-shaped structures 212. As shown in FIG. 4, the dummy gate stack 220 extends lengthwise along the Y direction to wrap over the fin-shaped structure 212. The dummy gate stack 220 includes a dummy dielectric layer 216 and a dummy gate electrode 218. To illustrate how the dummy gate stack 220 is disposed over the fin-shaped structure 212, a cross-sectional view along the cross-section A-A′ is provided in FIG. 5. As shown in FIG. 5, the portion of the fin-shaped structure 212 underlying the dummy gate stack 220 is a channel region 202C. The channel region 202C and the dummy gate stack 220 also define source/drain regions 202SD that are not vertically overlapped by the dummy gate stack 220. The channel region 202C is disposed between two source/drain regions 202SD. It is noted that because the cross-sectional view in FIG. 5 slices through the fin-shaped structure 212, the isolation feature 214 is not shown in FIG. 5.

In some embodiments, the dummy gate stack 220 is formed by various process steps such as layer deposition, patterning, etching, as well as other suitable processing steps. Exemplary layer deposition processes include low-pressure CVD (LPCVD), CVD, plasma-enhanced CVD (PECVD), PVD, ALD, thermal oxidation, e-beam evaporation, or other suitable deposition techniques, or combinations thereof. For example, the patterning process may include a lithography process (e.g., photolithography or e-beam lithography) which may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etching process may include dry etching (e.g., RIE etching), wet etching, and/or other etching methods. In an example process, the dummy dielectric layer 216, a dummy electrode layer for the dummy gate electrode 218, and a gate top hard mask layer 222 are sequentially deposited over the WIP structure 200, including over the fin-shaped structure 212. In some instances, the gate top hard mask layer 222 may be a multilayer and may include a first hard mask 223 and a second hard mask 224 over the first hard mask 223. The first hard mask 223 may include silicon oxide and the second hard mask 224 may include silicon nitride. The deposition may be done by using one of the aforementioned exemplary layer deposition processes. The dummy dielectric layer 216 and the dummy electrode layer are then patterned using photolithography processes to form the dummy gate stack 220. In some embodiments, the dummy dielectric layer 216 may include silicon oxide and the dummy gate electrode 218 may include polycrystalline silicon (polysilicon).

After the formation of the dummy gate stack 220, a gate spacer layer 226 is formed alongside sidewalls of the dummy gate stack 220. In some embodiments, the formation of the gate spacer layer 226 includes conformal deposition of one or more dielectric layers over the WIP structure 200 and etch-back of the gate spacer layer 226 from top-facing surfaces of the WIP structure 200. In an example process, the one or more dielectric layers are deposited using CVD, SACVD, or ALD and are etched back in an anisotropic etch process to form the gate spacer layer 226. The gate spacer layer 226 may include silicon oxide, silicon nitride, silicon carbide, silicon oxynitride, silicon carbonitride, silicon oxycarbide, silicon oxycarbonitride, and/or combinations thereof.

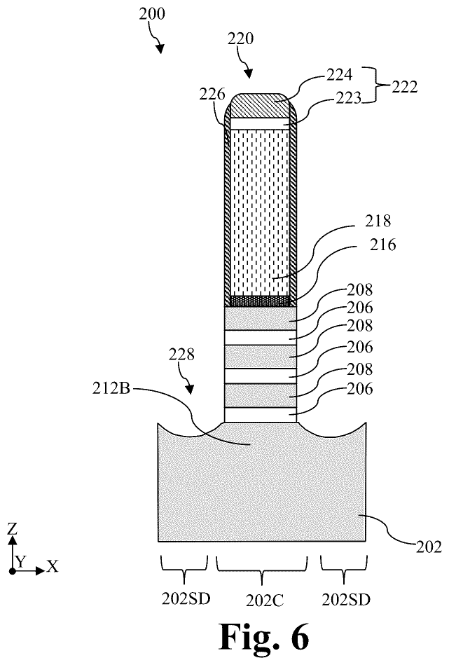

Referring to FIGS. 1 and 6, method 100 includes a block 108 where source/drain trenches 228 are formed in the fin-shaped structure 212. In embodiments represented in FIG. 6, the source/drain regions 202SD of the fin-shaped structure 212, which are not masked by the gate top hard mask layer 222 and the gate spacer layer 226, are recessed to form the source/drain trenches 228. The etch process at block 108 may be a dry etch process or a suitable etch process. For example, the dry etch process may implement an oxygen-containing gas, hydrogen, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBR₃), an iodine-containing gas, other suitable gases and/or plasmas, and/or combinations thereof. As shown in FIG. 6, sidewalls of the sacrificial layers 206 and the channel layers 208 are exposed in the source/drain trenches 228.

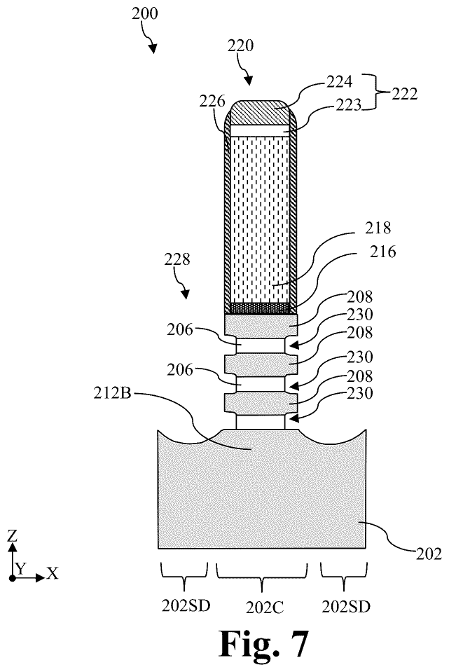

Referring to FIGS. 1 and 7, method 100 includes a block 110 where inner spacer recesses 230 are formed. At block 110, the sacrificial layers 206 exposed in the source/drain trenches 228 are selectively and partially recessed to form inner spacer recesses 230, while the exposed channel layers 208 are moderately etched. In an embodiment where the channel layers 208 consist essentially of silicon (Si) and sacrificial layers 206 consist essentially of silicon germanium (SiGe), the selective and partial recess of the sacrificial layers 206 may include a SiGe oxidation process followed by a SiGe oxide removal. In that embodiment, the SiGe oxidation process may include use of ozone (O₃). In some other embodiments, the selective recess may be a selective isotropic etching process (e.g., a selective dry etching process or a selective wet etching process), and the extent at which the sacrificial layers 206 are recessed is controlled by duration of the etching process. The selective dry etching process may include use of one or more fluorine-based etchants, such as fluorine gas or hydrofluorocarbons. The selective wet etching process may include a hydro fluoride (HF) or NH₄OH etchant. As shown in FIG. 7, the channel layers 208 may be moderately etched at block 110 and the inner spacer recesses 230 may partially extend along the Z direction into the channel layers 208. Each of the inner spacer recesses 230 has a depth (along the X direction) between about 2 nm and about 5 nm and a height (along the Z direction) between about 7 nm and about 12 nm. Put differently, each of the inner spacer recesses 230 has a height greater than its depth.

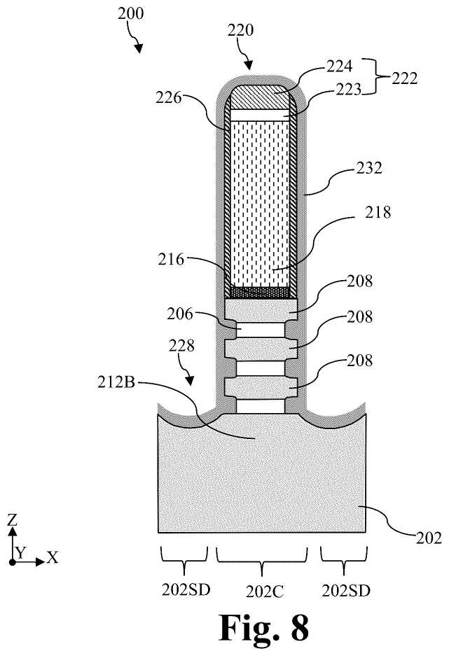

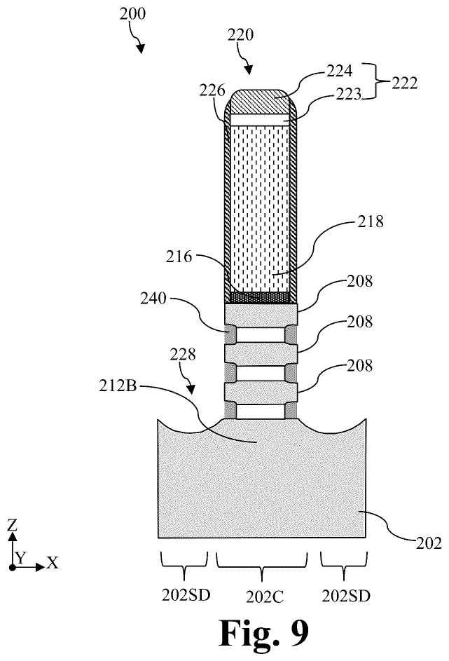

Referring to FIGS. 1, 8 and 9, method 100 includes a block 112 where inner spacer features 240 are formed in the inner spacer recesses 230. Operations at block 112 may include deposition of an inner spacer material layer 232 (shown in FIG. 8) and etching back the inner spacer material layer 232 to form the inner spacer features 240 (shown in FIG. 9. The inner spacer material layer 232, illustrated in FIG. 8, may be deposited using ALD and may include silicon (Si), carbon (C), oxygen (O), and nitrogen. In some embodiments, the inner spacer material layer 232 may include silicon oxycarbonitride. In some alternative embodiments, the inner spacer material layer 232 may include silicon carbonitride. Referring to FIG. 9, the deposited inner spacer material layer 232 is etched back to form inner spacer features 240. At block 112, the etch back process removes the inner spacer material layer 232 on the channel layers 208, the substrate 202, and the gate spacer layer 226 to form the inner spacer features 240 in the inner spacer recesses 230. In some embodiments, the etch back process at block 112 may be a dry etch process that includes use of an oxygen-containing gas, hydrogen, nitrogen, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas (e.g., CF₃I), other suitable gases and/or plasmas, and/or combinations thereof. As described above, each of the inner spacer recesses 230 has a depth (along the X direction) between about 2 nm and about 5 nm and a height (along the Z direction) between about 7 nm and about 12 nm. Because each of the inner spacer features 240 is formed into an inner spacer recess 230, each of the inner spacer features may also have a depth (along the X direction) between about 2 nm and about 5 nm and a height (along the Z direction) between about 7 nm and about 12 nm. Put differently, each of the inner spacer features 240 has a height (along the Z direction) greater than its depth (along the X direction).

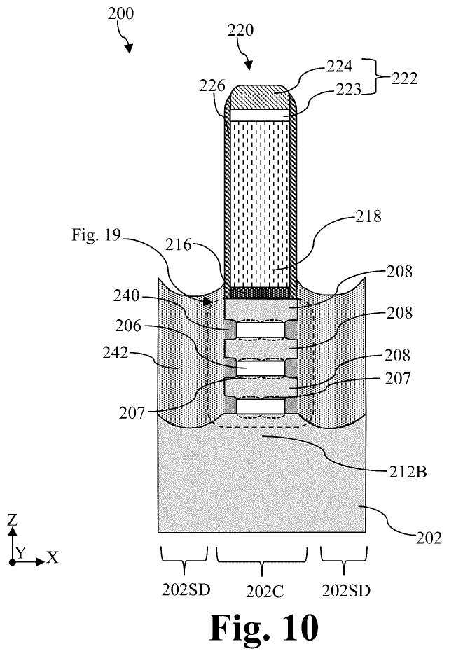

Referring to FIGS. 1 and 10, method 100 includes a block 114 where source/drain features 242 are formed in the source/drain trenches 228. In some embodiments, the source/drain features 242 may be formed using an epitaxial process, such as VPE, UHV-CVD, MBE, and/or other suitable processes. The epitaxial growth process may use gaseous and/or liquid precursors, which interact with the composition of the substrate 202 as well as the channel layers 208. In some embodiments, the epitaxial growth process may include a process temperature between about 350° C. and about 500° C. Depending on the conductivity type of the to-be-formed GAA transistor, the source/drain features 242 may be n-type source/drain features or p-type source/drain features. Example n-type source/drain features may include Si, GaAs, GaAsP, SiP, or other suitable material and may be in-situ doped during the epitaxial process by introducing an n-type dopant, such as phosphorus (P), arsenic (As), or ex-situ doped using an implantation process (i.e., a junction implant process). Example p-type source/drain features may include Si, Ge, AlGaAs, SiGe, boron-doped SiGe, or other suitable material and may be in-situ doped during the epitaxial process by introducing a p-type dopant, or ex-situ doped using an implantation process (i.e., a junction implant process).

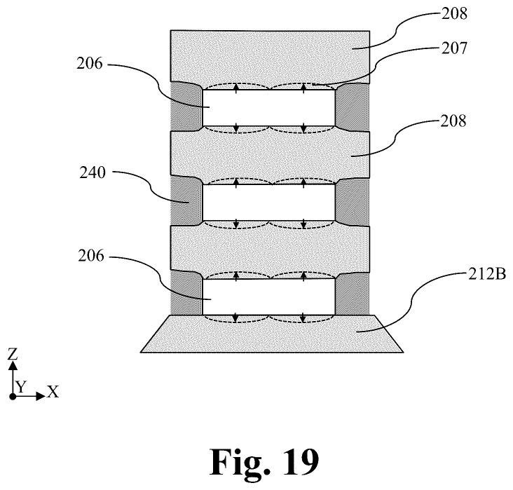

Reference is made to FIG. 10 and the enlarged view of the channel region 202C in FIG. 19. The elevated temperature may cause intermixing between the composition of the sacrificial layers 206 and the composition of the channel layers 208. The intermixing forms an intermixed layer 207 that has a germanium content greater than that of the channel layers 208 but lower than that of the sacrificial layers 206. In terms of silicon content, the intermixed layer 207 includes more silicon than the sacrificial layers 206 but less silicon than the channel layers 208. The increased germanium content of the intermixed layer 207 provides an etch selectivity between that of the channel layers 208 and that of the sacrificial layers 206. That is, when the sacrificial layers 206 are selectively removed in a subsequent step, a portion or all of the intermixed layer 207 may also be removed. Similar intermixed layer 207 is also observed adjacent a top surface of the base portion 212B. In some instances, the intermixed layer 207 does not have uniform thickness along the length of the channel layers 208 and may have a wavy profile as shown in FIG. 10 and FIG. 19.

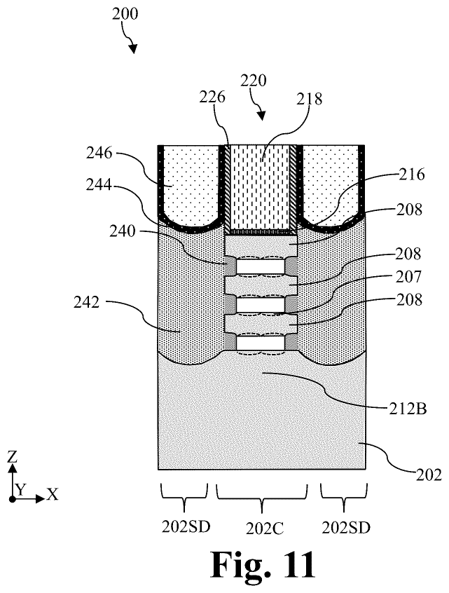

Referring to FIGS. 1 and 11, method 100 includes a block 116 where a contact etch stop layer (CESL) 244 and an interlayer dielectric (ILD) layer 246 are deposited over the WIP structure 200. The CESL 244 may include silicon nitride, silicon oxide, silicon oxynitride, and/or other materials known in the art and may be formed by ALD, plasma-enhanced chemical vapor deposition (PECVD) process and/or other suitable deposition or oxidation processes. As shown in FIG. 11, the CESL 244 may be deposited on top surfaces of the source/drain features 242 and along sidewalls of the gate spacer layer 226. Although the CESL 244 is also deposited over the top surface of the gate spacer layer 226 and the gate top hard mask layer 222, FIG. 11 only illustrates cross-sectional views after the gate top hard mask layer 222 is removed. Block 116 also includes depositing of the ILD layer 246 over the CESL 244. In some embodiments, the ILD layer 246 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer 246 may be deposited by a PECVD process or other suitable deposition technique. In some embodiments, after formation of the ILD layer 246, the WIP structure 200 may be annealed to improve integrity of the ILD layer 246. To remove excess materials and to expose top surfaces of the dummy gate stacks 220, a planarization process, such a chemical mechanical polishing (CMP) process may be performed, as illustrated in FIG. 11. The gate top hard mask layer 222 is removed by the planarization process.

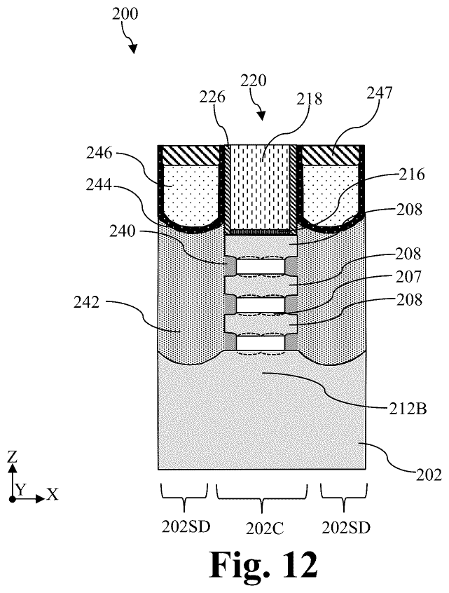

Referring to FIGS. 1 and 12, method 100 includes a block 118 where a protective layer 247 is deposited over the ILD layer 246. In order to protect the ILD layer 246 from being damaged during gate replacement steps, the ILD layer 246 is selectively recessed to form a top recess and a protective layer 247 is formed over the top recess. The protective layer 247 is formed of a material different than that of the ILD layer 246. When the ILD layer 246 includes silicon oxide, the protective layer 247 may include silicon nitride, silicon carbonitride, silicon carbide, or silicon oxycarbonitride. In one embodiment, the protective layer 247 may include silicon nitride. Another planarization is performed to remove excess protective layer 247 and to expose the dummy gate stack 220. After the planarization, top surfaces of the protective layer 247, the CESL 244, the gate spacer layer 226, and the dummy gate stacks 220 are coplanar.

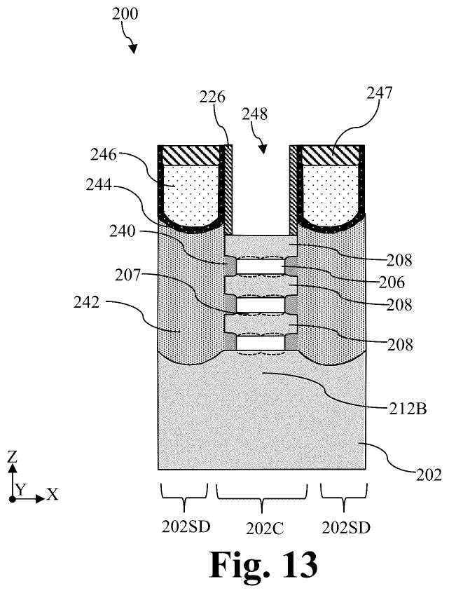

Referring to FIGS. 1 and 13, method 100 includes a block 120 where the dummy gate stack 220 is removed. Exposure of the dummy gate stack 220 at block 118 allows the removal thereof at block 120. The removal of the dummy gate stack 220 may include one or more etching processes that are selective to the material of the dummy gate stack 220. The removal of the dummy gate stack 220 results in a gate trench 248 over the channel regions 202C. A gate structure 250 (to be described below) may be subsequently formed in the gate trench 248, as will be described below. The removal of the dummy gate stack 220 may include one or more etching processes that are selective to the material in the dummy gate stack 220. For example, the removal of the dummy gate stack 220 may be performed using as a selective wet etch, a selective dry etch, or a combination thereof. After the removal of the dummy gate stack 220, sidewalls of the channel layers 208 and sacrificial layers 206 in the channel regions 202C are exposed in the gate trench 248.

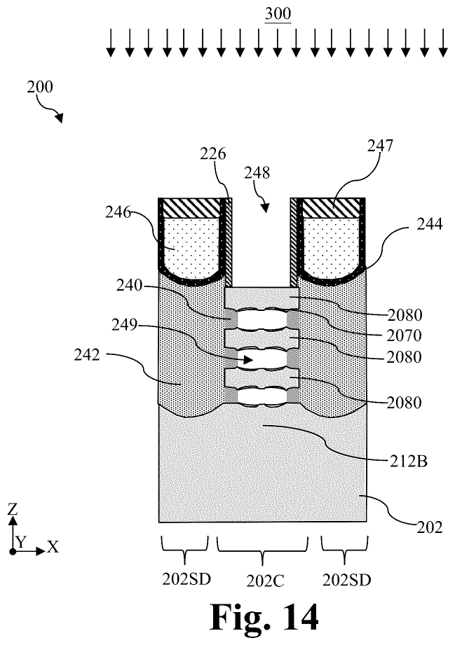

Referring to FIGS. 1 and 14, method 100 includes a block 122 where the sacrificial layers 206 in the channel region 202C are selectively removed to release the channel members 2080. After the removal of the dummy gate stack 220, block 122 of method 100 may include operations to selectively remove the sacrificial layers 206 between the channel layers 208 in the channel regions 202C. The selective removal of the sacrificial layers 206 releases the channel layers 208 to form channel members 2080. The selective removal of the sacrificial layers 206 may be implemented by a selective dry etch process 300. In some embodiments, the selective dry etch process 300 includes use of CF₄, CF₂Cl₂, CCl₄, BCl₃, or HCl in its gaseous form or radical form. The selective dry etch process 300 is configured to completely remove the sacrificial layers 206. Because the composition of the intermixed layer 207 is between that of the channel layers 208 and the sacrificial layers 206, at least a portion of the intermixed layer 207 may be removed to form the residual intermixed layer 2070. In the depicted embodiments, the residual intermixed layer 2070 may be present on surfaces of the channel layers 208 and base fin 212B that were once in contact with a sacrificial layer 206. The selective removal of the sacrificial layers 206 also forms the inter-member openings 249. Each of the inter-member openings 249 is vertical disposed between two residual intermixed layers 2070.

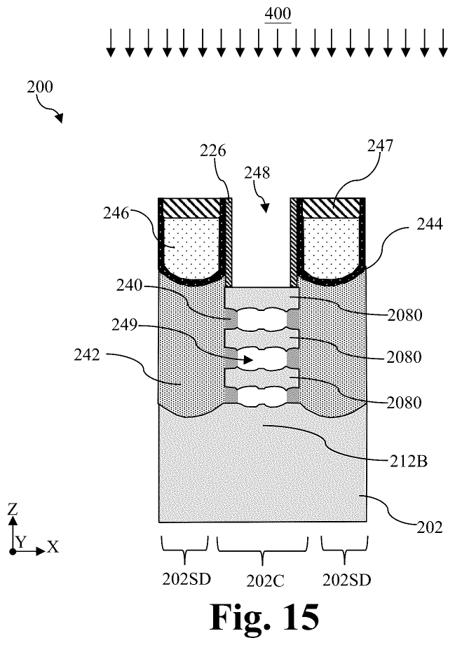

Referring to FIGS. 1 and 15, method 100 includes a block 124 where the channel members 2080 are trimmed. Because rough channel member surfaces and presence of the residual intermixed layers 2070 may impact device performance, the channel members 2080 released at block 122 undergo a cleaning process 400 to selectively remove the residual intermixed layers 2070. In some embodiments, the cleaning process 400 includes a wet etch that includes use of hydrogen fluoride (HF), ozonated deionized water (DIO₃), ammonium hydroxide (NH₄OH), hydrogen peroxide (H₂O₂), or a mixture thereof. The cleaning process 400 is configured to remove or oxidize the residual intermixed layer 2070 and trim the channel members 2080. Aqueous hydrogen fluoride (HF), fluorine radical etching, or gas phase reaction may be used in an oxide removal process to remove the oxidized residual intermixed layer 2070. An example fluorine radical etching may include fluorine-containing gas such as NF₃ (nitrogen trifluoride), SF₆ (sulfur hexafluoride), CF₄ (carbon tetrafluoride), OF₂ (oxygen difluoride), HF (hydrogen fluoride), or a mixture thereof and a hydrogen-containing gas such as ammonia (NH₃), hydrogen (H₂), water (H₂O), or a combination thereof. An example gas phase reaction may include use of hydrogen fluoride (HF), ammonia (NH₃), alkylamine (CₓH_{y}NH₂), or a combination thereof. The cleaning process 400 and the oxide removal process also trim the channel members 2080. In some alternative embodiments, operations at block 124 are omitted.

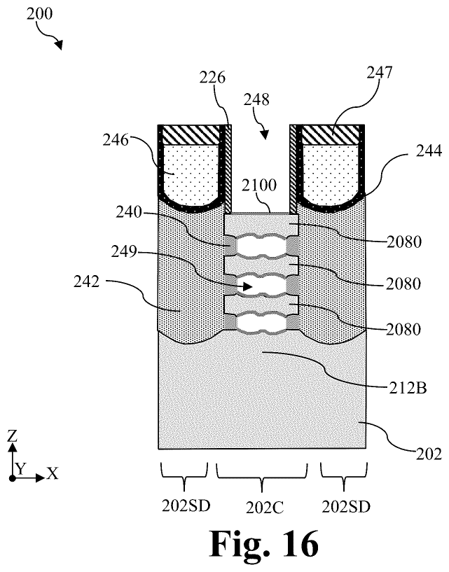

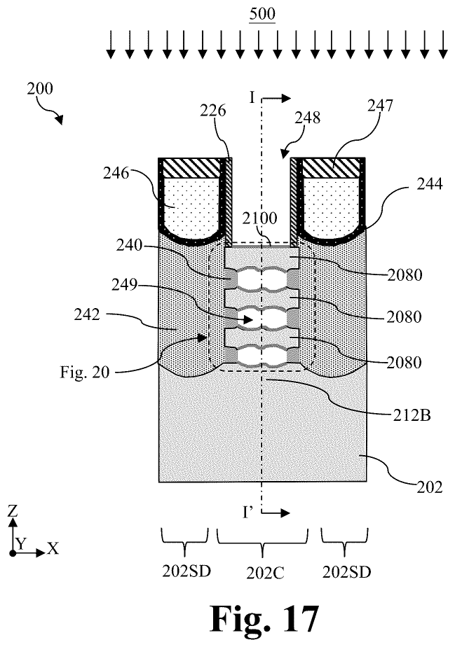

Referring to FIGS. 1, 16 and 17, method 100 includes a block 126 where a silicon liner 2100 is formed over the channel members 2080. Referring to FIG. 16, the silicon liner 2100 is epitaxially deposited in order to achieve a smoother surface for the channel members 2080. In some embodiments, the silicon liner 2100 may be deposited using vapor-phase epitaxy (VPE), ultra-high vacuum chemical vapor deposition (UHV-CVD), molecular beam epitaxy (MBE), and/or other suitable processes. In some instances, the silicon liner 2100 may have a thickness between about 0.3 nm and about 1.5 nm. The deposition of the silicon liner 2100 on the channel members 2080 (and the base fin 212B) may also be referred to as a silicon re-deposition process. To reduce defects, an anneal process 500 may be performed after the deposition of the silicon liner 2100, as illustrated in FIG. 17. In some embodiments, the anneal process may include an anneal temperature between about 400° C. and about 900° C. in an ambient having nitrogen (N₂), hydrogen (H₂), or helium (He). In some instances, the anneal process may include a process pressure between about 0.1 Torr and about 300 Torr. In some alternative embodiments, operations at block 126 are omitted.

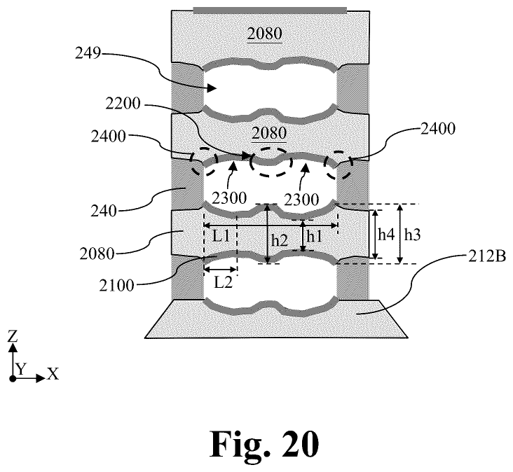

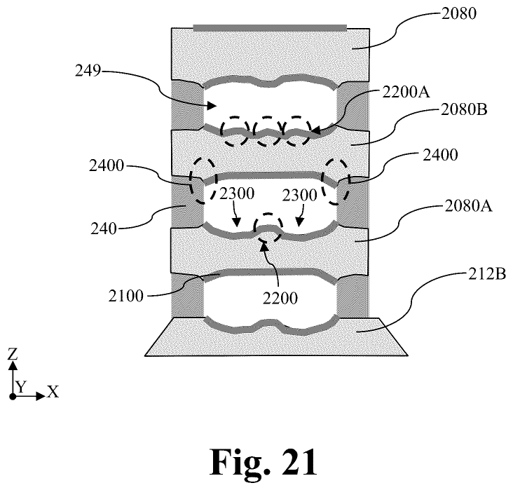

The annealing at block 126 may cause silicon atom surface migration to reduce surface roughness. Silicon atoms in the silicon liner 2100 may migrate along the surfaces of the channel members 2080 and a top surface of the base fin 212B to achieve a smoother surface. Despite of the surface leveling during the anneal process 500, the channel members 2080 and the top surface of the base fin 212B may still include slightly wavy or concave surfaces. The channel region 212C in FIG. 17 is enlarged in FIG. 20 to schematically show example profiles of the channel members 2080 when view along the channel width direction (or the Y direction, which is perpendicular to the channel current direction, i.e., the X direction). FIG. 20 illustrates an example surface profile of the channel members 2080 where a top surface and a bottom surface of each of the channel member 2080 includes a middle protrusion 2200 disposed between to two edge protrusions 2400. Each of the two edge protrusions 2400 and the middle protrusion 2200 define a surface recess 2300. Each of the edge protrusions 2400 is disposed adjacent or at an interface with the inner spacer feature 240. As illustrated in FIG. 20, each of the channel members 2080 includes a minimum height h1 wherein a height of the channel member 2080 is the smallest and an edge height h3 defined between two opposing edge protrusions 2400. In some instances, the minimum height h1 is between about 2 nm and about 8 nm and the edge height h3 is between about 3 nm and about 10 nm. The edge height h3 is greater than the minimum height h1. In some instances, a difference between the edge height h3 and the minimum height h1 is between 0 nm and about 6 nm. Each of the channel members 2080 also include a middle height h2 defined between tips of two opposing middle protrusions 2200 and an end height h4 at end surfaces of the channel member 2080. In some instances, the end height h4 is greater than the minimum height h2 and edge height h3 is greater than the middle height h2. Along the gate length direction (i.e., X direction in FIG. 20), each of the channel members 2080 includes a channel length L1 and a recess length L2 from the edge protrusion 2400 and a location of the minimum height h2. In some embodiments, the channel length L1 is between about 5 nm and about 30 nm and the recess length L2 is smaller than one half of the channel length L1. The top surface of the base fin 212B may also include a middle protrusion 2200 disposed between to surface recesses 2300. In some embodiments represented in FIG. 20, because the top surface of the topmost channel member 2080 never interfaces any of the sacrificial layers 206, the top surface of the topmost channel member 2080 is substantially flat. In some alternative embodiments, the top surface and the bottom surface of each of the channel member 2080 may include more than one protrusion similar to the middle protrusions or even no protrusion at all. Reference is made to FIG. 21. A channel member 2080A in FIG. 21 includes a single middle protrusion 2200 on its top surface but no middle protrusion 2200 on its bottom surface. A channel member 2080B in FIG. 21 includes multiple protrusion 2200A (such as between 2 and 5) on its top surface but no middle protrusion 2200 on its bottom surface.

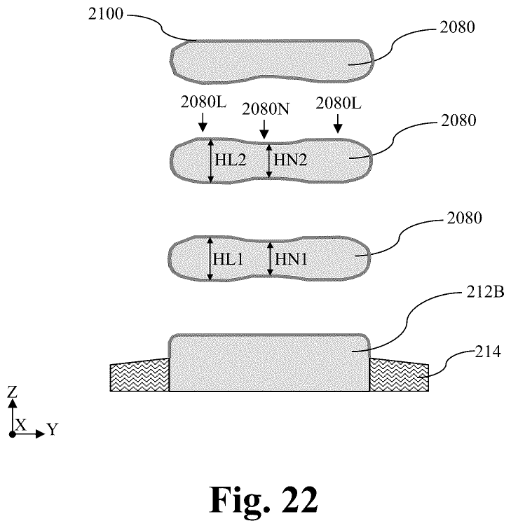

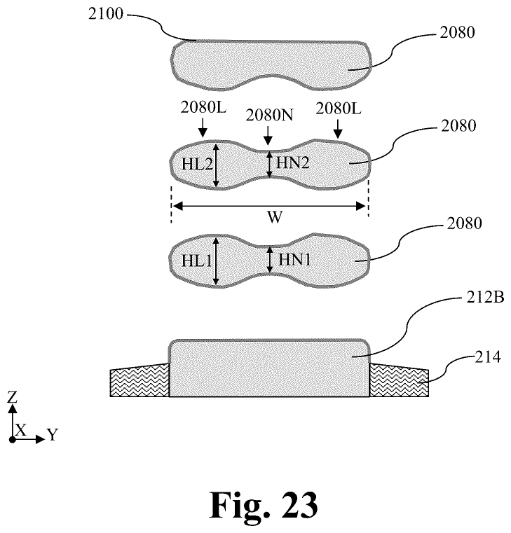

FIGS. 22 and 23 illustrate enlarged cross-sectional view of the channel members 2080 along cross-section I-I′ in FIG. 17. As shown in FIGS. 22 and 23, when viewed along the channel length direction (or the X direction, which is perpendicular to the channel width direction, i.e., the Y direction), each of the channel members 2080 may have a shape similar to a double-sided maraca. That is, each of the channel members 2080 may include two lobe portions 2080L sandwiching a narrower neck portion 2080N. Along the Y direction (i.e., channel width direction), each of the channel members 2080 does not have a constant thickness. Each of the two lobe portions 2080L includes a rounded end surface that has a curvature smaller than 2 nm⁻¹. In FIGS. 22 and 23, each of two lobe portions 2080L of the bottom channel member 2080 includes a first lobe height HL1 and the neck portion 2080N of the bottom channel member 2080 includes a first neck height HN1. Each of two lobe portions 2080L of the middle channel member 2080 includes a second lobe height HL2 and the neck portion 2080N of the middle channel member 2080 includes a second neck height HN2. The first lobe height HL1 is greater than the first neck height HN1 and the second lobe height HL2 is greater than the second neck height HN2. The bottom channel member 2080 is thicker than the middle channel member 2080. In some embodiments, the first neck height HN1 is greater than the second neck height HN2 and the first lobe height HL1 is greater than the second lobe height HL2. The first lobe height HL1, the second lobe height hL2, the first neck height HN1, and the second neck height HN2 may be between about 1 nm and about 10 nm. Along the gate width direction, each of the channel members 2080 may have a channel width W, which may be between about 5 nm and about 90 nm.

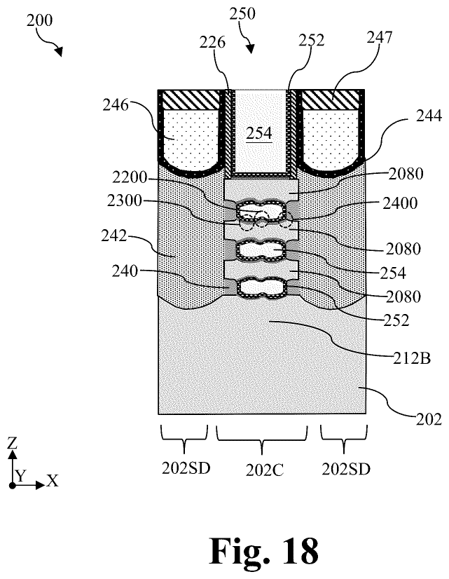

Referring to FIGS. 1 and 18, method 100 include a block 128 where a gate structure 250 is formed over and around the channel members 2080, including into the inter-member openings 249 (shown in FIG. 15). At block 128, the gate structure 250 is formed within the gate trench 248 (shown in FIG. 14) over the WIP structure 200 and is deposited in the inter-member openings 249 left behind by the removal of the sacrificial layers 206 in the channel regions 202C. In this regard, the gate structure 250 wraps around each of the channel members 2080 on the Y-Z plane. In some embodiments, the gate structure 250 includes a gate dielectric layer 252 and a gate electrode 254 formed over the gate dielectric layer 252. In an example process, formation of the gate structure 250 may include deposition of the gate dielectric layer 252, deposition of the gate electrode 254, and a planarization process to remove excess material.

In some embodiments, the gate dielectric layer 252 may include an interfacial layer and a high-k dielectric layer. High-K gate dielectrics, as used and described herein, include dielectric materials having a high dielectric constant, for example, greater than that of thermal silicon oxide (˜3.9). The interfacial layer may include a dielectric material such as silicon oxide, hafnium silicate, or silicon oxynitride. The interfacial layer may be deposited using chemical oxidation, thermal oxidation, ALD, CVD, and/or other suitable method. The high-K dielectric layer may include a high-K dielectric layer such as hafnium oxide. Alternatively, the high-K dielectric layer may include other high-K dielectrics, such as titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO₂), lanthanum oxide (La₂O₃), aluminum oxide (Al₂O₃), zirconium oxide (ZrO), yttrium oxide (Y₂O₃), SrTiO₃ (STO), BaTiO₃ (BTO), BaZrO, hafnium lanthanum oxide (HfLaO), lanthanum silicon oxide (LaSiO), aluminum silicon oxide (AlSiO), hafnium tantalum oxide (HfTaO), hafnium titanium oxide (HfTiO), (Ba,Sr)TiO₃ (BST), silicon nitride (SiN), silicon oxynitride (SiON), combinations thereof, or other suitable material. The high-K dielectric layer may be formed by ALD, physical vapor deposition (PVD), CVD, oxidation, and/or other suitable methods.

The gate electrode 254 of the gate structure 250 may include a single layer or alternatively a multi-layer structure, such as various combinations of a metal layer with a selected work function to enhance the device performance (work function metal layer), a liner layer, a wetting layer, an adhesion layer, a metal alloy or a metal silicide. By way of example, the gate electrode 254 may include titanium nitride (TiN), titanium aluminum (TiAl), titanium aluminum nitride (TiAlN), tantalum nitride (TaN), tantalum aluminum (TaAl), tantalum aluminum nitride (TaAlN), tantalum aluminum carbide (TaAlC), tantalum carbonitride (TaCN), aluminum (Al), tungsten (W), nickel (Ni), titanium (Ti), ruthenium (Ru), cobalt (Co), platinum (Pt), tantalum carbide (TaC), tantalum silicon nitride (TaSiN), copper (Cu), other refractory metals, or other suitable metal materials or a combination thereof. In various embodiments, the gate electrode 254 may be formed by ALD, PVD, CVD, e-beam evaporation, or other suitable process. Further, the gate electrode may be formed separately for n-type transistors and p-type transistors, which may use different metal layers (e.g., for providing different n-type and p-type work function metal layers). In various embodiments, a planarization process, such as a CMP process, may be performed to remove excessive materials for both the gate dielectric layer 252 and the gate electrode 254, and thereby provide a substantially planar top surface of the gate structure 250. In some embodiments, because the inner spacer features 240 are exposed in the inter-member openings 249 (shown in FIG. 14) and the gate structure 250 fills the inter-member openings 249, the gate structure 250 is in contact with the inner spacer features 240.

It is noted that the formation of the gate structure 250 does not substantially alter the shape and profile of the channel members 2080. That is, the description associated with the channel members 2080 in FIGS. 17 and 20-22 generally holds true with respect to the channel members 2080 shown in FIG. 18. For example, a top surface and a bottom surface of each of the channel member 2080 includes a middle protrusion 2200 disposed between to two edge protrusions 2400. Each of the two edge protrusions 2400 and the middle protrusion 2200 define a surface recess 2300. Each of the edge protrusions 2400 is disposed adjacent or at an interface with the inner spacer feature 240. In some alternative embodiments not illustrated in the drawings, the top surface and the bottom surface of each of the channel member 2080 may include two edge protrusions 2400 and more than one middle protrusion 2200. The top surface of the base fin 212B may also include a middle protrusion 2200 disposed between to surface recesses 2300. In some embodiments represented in FIG. 18, because the top surface of the topmost channel member 2080 never interfaces any of the sacrificial layers 206, the top surface of the topmost channel member 2080 is substantially flat.

In one exemplary aspect, the present disclosure is directed to a method. The method includes forming a fin-shaped structure over a substrate, the fin-shaped structure including a plurality of channel layers interleaved a plurality of sacrificial layers, forming a dummy gate stack over a channel region of the fin-shaped structure, forming a gate spacer layer along sidewalls of the dummy gate stack, recessing source/drain regions to form source/drain trenches and to expose sidewalls of the plurality of channel layers and the plurality of sacrificial layers, selectively and partially etching the plurality of sacrificial layers to form inner spacer recesses, forming inner spacer features in the inner spacer recesses, forming source/drain features in the source/drain trenches, removing the dummy gate stack, selectively etching the plurality of sacrificial layers to release the plurality of channel layers in the channel region as a plurality of channel members, cleaning the plurality of channel members, after the cleaning, epitaxially depositing a semiconductor layer over surfaces of the plurality of channel members, after the epitaxially depositing, annealing the semiconductor layer, and forming a gate structure to wrap around each of the plurality of channel members.

In some embodiments, the plurality of channel layers include silicon and the plurality of sacrificial layers include silicon germanium. In some embodiments, after the forming of the source/drain features, an intermixed layer is formed at an interface between one of the plurality of channel layers and one of the plurality of sacrificial layers. A silicon content of the intermixed layer is greater than a silicon content of the plurality of sacrificial layers and a germanium content of the intermixed layer is greater than a silicon germanium content of the plurality of channel layers. In some implementations, the selectively etching of the plurality of sacrificial layers etches the plurality of sacrificial layers faster than it etches the intermixed layer. In some embodiments, the selectively etching the plurality of sacrificial layers includes a dry etch process and the dry etch process includes use of CF₄, CF₂Cl₂, CCl₄, BCl₃, or HCl. In some instances, the cleaning includes a wet etch process and the wet etch process includes hydrogen fluoride, ozonated deionized water, ammonium hydroxide, hydrogen peroxide, or a mixture thereof. In some instances, the method further includes after the cleaning, performing an oxide removal process to the plurality of channel members. The oxide removal process includes use of aqueous hydrogen fluoride, nitrogen trifluoride, sulfur hexafluoride, carbon tetrafluoride, oxygen difluoride, ammonia, hydrogen, water, alkylamine, or a combination thereof. In some embodiments, the annealing includes a temperature between about 400° C. and about 900° C. in an ambient including nitrogen (N₂), hydrogen (H₂), or helium (He). In some embodiments, the semiconductor layer includes silicon (Si).

In another exemplary aspect, the present disclosure is directed to a method. The method includes forming a fin-shaped structure over a substrate, the fin-shaped structure including a base fin, and a stack over the base fin and including a plurality of silicon layers interleaved a plurality of silicon germanium layers, forming a dummy gate stack over a channel region of the fin-shaped structure, forming a gate spacer layer along sidewalls of the dummy gate stack, recessing source/drain regions of the fin-shaped structure to form source/drain trenches, selectively and partially etching the plurality of silicon germanium layers to form inner spacer recesses, forming inner spacer features in the inner spacer recesses, forming source/drain features in the source/drain trenches, removing the dummy gate stack, selectively etching the plurality of silicon germanium layers to release the plurality of silicon layers in the channel region as a plurality of channel members, the plurality of channel members including an intermixed surface layer, removing the intermixed surface layer from the plurality of channel members, after the removing, epitaxially depositing a silicon layer over surfaces of the plurality of channel members, after the epitaxially depositing, annealing the silicon layer, and forming a gate structure to wrap around each of the plurality of channel members.

In some embodiments, a silicon content of the intermixed surface layer is greater than a silicon content of the plurality of silicon germanium layers and a germanium content of the intermixed surface layer is greater than a silicon germanium content of the plurality of silicon layers. In some implementations, the selectively etching the plurality of silicon germanium layers includes a dry etch process and the dry etch process includes use of CF₄, CF₂Cl₂, CCl₄, BCl₃, or HCl. In some embodiments, the removing includes use of a wet etch process and the wet etch process includes hydrogen fluoride, ozonated deionized water, ammonium hydroxide, hydrogen peroxide, or a mixture thereof. In some embodiments, the annealing includes a temperature between about 400° C. and about 900° C. in an ambient including nitrogen (N₂), hydrogen (H₂), or helium (He). In some embodiments, after the selectively etching, a bottom intermixed surface layer is disposed over a top surface of the base fin. A germanium content of the bottom intermixed surface layer is greater than a silicon germanium content of the base fin.

In yet another exemplary aspect, the present disclosure is directed to a semiconductor structure. The semiconductor structure includes a base fin over a substrate, a first source/drain feature and a second source/drain feature over the base fin, a plurality of nanostructures extending between the first source/drain feature and the second source/drain feature along a first direction, and a gate structure wrapping around each of the plurality of nanostructures. When viewed along the first direction, each of the plurality of nanostructures has a shape of a double-sided maraca.

In some embodiments, the gate structure is spaced apart from the first source/drain feature by a first plurality of inner spacer features. The gate structure is spaced apart from the second source/drain feature by a second plurality of inner spacer features. In some implementations, each of the plurality of nanostructures includes a first bottom edge protrusion at an interface between the first source/drain feature and the first plurality of inner spacer features, and a second bottom edge protrusion at an interface between the second source/drain feature and the second plurality of inner spacer features. In some implementations, each of the plurality of nanostructures includes a middle bottom edge protrusion between the first bottom edge protrusion and the second bottom edge protrusion along the first direction. In some embodiments, when viewed along a second direction perpendicular to the first direction, a top surface of the base fin below the plurality of nanostructures includes a middle protrusion extending upward.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a fin-shaped structure over a substrate, the fin-shaped structure comprising a plurality of channel layers interleaved a plurality of sacrificial layers;
forming a dummy gate stack over a channel region of the fin-shaped structure;
forming a gate spacer layer along sidewalls of the dummy gate stack;
recessing source/drain regions to form source/drain trenches and to expose sidewalls of the plurality of channel layers and the plurality of sacrificial layers;
selectively and partially etching the plurality of sacrificial layers to form inner spacer recesses;
forming inner spacer features in the inner spacer recesses;
forming source/drain features in the source/drain trenches;
removing the dummy gate stack;
selectively etching the plurality of sacrificial layers to release the plurality of channel layers in the channel region as a plurality of channel members;
cleaning the plurality of channel members;
after the cleaning, epitaxially depositing a semiconductor layer over surfaces of the plurality of channel members;
after the epitaxially depositing, annealing the semiconductor layer; and
forming a gate structure to wrap around each of the plurality of channel members.

2. The method of claim 1,
wherein the plurality of channel layers comprise silicon,
wherein the plurality of sacrificial layers comprise silicon germanium.

3. The method of claim 2,
wherein, after the forming of the source/drain features, an intermixed layer is formed at an interface between one of the plurality of channel layers and one of the plurality of sacrificial layers,
wherein a silicon content of the intermixed layer is greater than a silicon content of the plurality of sacrificial layers,
wherein a germanium content of the intermixed layer is greater than a silicon germanium content of the plurality of channel layers.

4. The method of claim 3, wherein the selectively etching of the plurality of sacrificial layers etches the plurality of sacrificial layers faster than it etches the intermixed layer.

5. The method of claim 1,
wherein the selectively etching the plurality of sacrificial layers comprises a dry etch process,
wherein the dry etch process comprises use of CF₄, CF₂Cl₂, CCl₄, BCl₃, or HCl.

6. The method of claim 1,
wherein the cleaning comprises a wet etch process,
wherein the wet etch process comprises hydrogen fluoride, ozonated deionized water, ammonium hydroxide, hydrogen peroxide, or a mixture thereof.

7. The method of claim 1, further comprising:
after the cleaning, performing an oxide removal process to the plurality of channel members,
wherein the oxide removal process comprises use of aqueous hydrogen fluoride, nitrogen trifluoride, sulfur hexafluoride, carbon tetrafluoride, oxygen difluoride, ammonia, hydrogen, water, alkylamine, or a combination thereof.

8. The method of claim 1, wherein the annealing comprises a temperature between about 400° C. and about 900° C. in an ambient comprising nitrogen (N₂), hydrogen (H₂), or helium (He).

9. The method of claim 1, wherein the semiconductor layer comprises silicon (Si).

10. A method, comprising:
forming a fin-shaped structure over a substrate, the fin-shaped structure comprising:
a base fin, and
a stack over the base fin and comprising a plurality of silicon layers interleaved a plurality of silicon germanium layers;
forming a dummy gate stack over a channel region of the fin-shaped structure;
forming a gate spacer layer along sidewalls of the dummy gate stack;
recessing source/drain regions of the fin-shaped structure to form source/drain trenches;
selectively and partially etching the plurality of silicon germanium layers to form inner spacer recesses;
forming inner spacer features in the inner spacer recesses;
forming source/drain features in the source/drain trenches;
removing the dummy gate stack;
selectively etching the plurality of silicon germanium layers to release the plurality of silicon layers in the channel region as a plurality of channel members, the plurality of channel members comprising an intermixed surface layer;
removing the intermixed surface layer from the plurality of channel members;
after the removing, epitaxially depositing a silicon layer over surfaces of the plurality of channel members;
after the epitaxially depositing, annealing the silicon layer; and
forming a gate structure to wrap around each of the plurality of channel members.

11. The method of claim 10,
wherein a silicon content of the intermixed surface layer is greater than a silicon content of the plurality of silicon germanium layers,
wherein a germanium content of the intermixed surface layer is greater than a silicon germanium content of the plurality of silicon layers.

12. The method of claim 10,
wherein the selectively etching the plurality of silicon germanium layers comprises a dry etch process,
wherein the dry etch process comprises use of CF₄, CF₂Cl₂, CCl₄, BCl₃, or HCl.

13. The method of claim 10,
wherein the removing comprises use of a wet etch process,
wherein the wet etch process comprises hydrogen fluoride, ozonated deionized water, ammonium hydroxide, hydrogen peroxide, or a mixture thereof.

14. The method of claim 10, wherein the annealing comprises a temperature between about 400° C. and about 900° C. in an ambient comprising nitrogen (N₂), hydrogen (H₂), or helium (He).

15. The method of claim 10,
wherein, after the selectively etching, a bottom intermixed surface layer is disposed over a top surface of the base fin,
wherein a germanium content of the bottom intermixed surface layer is greater than a silicon germanium content of the base fin.

16. A semiconductor structure, comprising:
a base fin over a substrate;
a first source/drain feature and a second source/drain feature over the base fin;
a plurality of nanostructures extending between the first source/drain feature and the second source/drain feature along a first direction; and
a gate structure wrapping around each of the plurality of nanostructures,
wherein, when viewed along the first direction, each of the plurality of nanostructures has a shape of a double-sided maraca.

17. The semiconductor structure of claim 16,
wherein the gate structure is spaced apart from the first source/drain feature by a first plurality of inner spacer features,
wherein the gate structure is spaced apart from the second source/drain feature by a second plurality of inner spacer features.

18. The semiconductor structure of claim 17, wherein each of the plurality of nanostructures comprises:
a first bottom edge protrusion at an interface between the first source/drain feature and the first plurality of inner spacer features, and
a second bottom edge protrusion at an interface between the second source/drain feature and the second plurality of inner spacer features.

19. The semiconductor structure of claim 18, wherein each of the plurality of nanostructures comprises:
a middle bottom edge protrusion between the first bottom edge protrusion and the second bottom edge protrusion along the first direction.

20. The semiconductor structure of claim 17, wherein when viewed along a second direction perpendicular to the first direction, a top surface of the base fin below the plurality of nanostructures comprises a middle protrusion extending upward.
